(19) United States
(12) Patent Application Publication
(10) Pub. No.: US 2026/0147055 A1
(43) Pub. Date: May 28, 2026

(54) DIAGNOSTIC DEVICE FOR LITHIUM ION BATTERY, DIAGNOSTIC METHOD FOR LITHIUM ION BATTERY, AND LITHIUM ION BATTERY

(71) Applicants: Hyundai Motor Company, Seoul (KR); Kia Corporation, Seoul (KR)

(72) Inventors: Yoon Ji Lee, Hwaseong (KR); Yeji Son, Hwaseong (KR); SungHoon Lim, Hwaseong (KR); Youngwoo Lee, Hwaseong (KR)

(21) Appl. No.: 19/178,500

(22) Filed: Apr. 14, 2025

(30) Foreign Application Priority Data
Oct. 8, 2024 (KR) 10-2024-0136345

(51) Int. Cl. G01R 31/3835; G01R 19/10; G01R 19/165; G01R 31/378; G01R 31/392

(52) U.S. Cl. CPC G01R 31/3835; G01R 19/10; G01R 19/16528; G01R 19/16542; G01R 31/378; G01R 31/392

(57) ABSTRACT

A system, method, and lithium-ion battery design are described for diagnosing battery performance using open-circuit voltage (OCV) measurements. A diagnostic device or method acquires a first OCV and a second OCV, calculates their difference (ΔV), and compares parameters—such as OCV or ΔV—to thresholds (e.g., about 3.0 V or 0.12). If the second OCV appears after about 200 charge-discharge cycles, or if ΔV is about 0.12 or lower, the battery is deemed to have extended life. The lithium-ion battery includes an anode containing silicon (about 5 to 15 wt %) with a capacity of about 380 to 500 mAh/g, which helps achieve improved cycle performance.

### CROSS-REFERENCE TO RELATED APPLICATION

This present application claims under 35 U.S.C. § 119(a) the benefit of Korean Patent Application No. 10-2024-0136345, entitled “Diagnostic device for lithium-ion battery, diagnostic method for lithium-ion battery and lithium ion battery” filed on Oct. 8, 2024, in the Korean Intellectual Property Office, the entire disclosure of which is incorporated herein by reference.

### TECHNICAL FIELD

The present disclosure relates to a diagnostic device for a lithium-ion battery, a diagnostic method for a lithium-ion battery, and a lithium-ion battery.

### BACKGROUND

With the rapid development of the electronics, communications, and computer industries, the application fields of energy storage technology are expanding to camcorders, mobile phones, laptops, PCs, and even electric vehicles. Accordingly, the development of lightweight, long-lasting, and highly reliable high-performance secondary batteries is underway.

Among the secondary batteries currently being applied, lithium-ion batteries developed in the early 1990s have a higher operating voltage and much higher energy density than the conventional batteries such as Ni-MH, Ni—Cd, and sulfuric acid-lead batteries that use aqueous electrolytes, and thus, have been adopted as a power source for many portable devices.

Materials including graphite have been widely used as an anode active material of the lithium-ion battery. Since the average potential when graphite absorbs/releases lithium is approximately 0.1 to 0.2 V (based on Li/Li+) and the discharge potential is relatively flat, there is an advantage in that the voltage of a battery using graphite is high and constant. However, there is a disadvantage in that graphite has a very small theoretical capacity of 372 mAh/g.

Therefore, various anode active materials are being studied to further increase the capacity of lithium-ion batteries. As a high-capacity anode active material, materials that form intermetallic compounds with lithium, such as silicon or tin, are expected to be promising anode active materials. In particular, silicon is an alloy type anode active material with a theoretical capacity (4,200 mAh/g) that is about 10 times higher than that of graphite and is attracting attention as a next-generation anode active material.

However, silicon-based anode active materials undergo a large volume change (˜300%) during charge and discharge. As a result, physical contact between active materials is broken, and fragmentation occurs. Consequently, ionic conductivity, electrical conductivity, etc., deteriorate rapidly, and life characteristics tend to decrease rapidly.

Therefore, there is a growing demand for technology that can more accurately diagnose and predict the performance of a lithium-ion battery using silicon as an anode active material.

### SUMMARY

Some embodiments of the present disclosure are to provide a diagnostic device for a lithium-ion battery, a diagnostic method for a lithium-ion battery, and a lithium-ion battery.

According to some embodiments of the present disclosure, a diagnostic device for a lithium ion battery may comprise: a data acquisition unit that acquires a first open circuit voltage (OCV) at a first time point and a second OCV at a second time point; a calculation unit that calculates AV which is a difference between the first OCV and the second OCV; and a control unit that compares at least any one of the first OCV, the inflection point, and AV with a threshold value.

In a diagnostic device for a lithium-ion battery according to some embodiments of the present disclosure, the first OCV may be a first OCV during OCV measurement, and the second OCV may be an OCV at the inflection point.

In a diagnostic device for a lithium ion battery according to some embodiments of the present disclosure, the first OCV and the second OCV may be termination voltages of a rest period after discharging, under a condition that the discharging is performed in a CC mode with a constant current of 1 C up to 2.5 V and then charging is performed in a CC/CV mode with a constant current of 1 C up to 4.2 V (0.1 C cutoff).

In a diagnostic device for a lithium-ion battery according to some embodiments of the present disclosure, the control unit may determine whether ΔV is 0.120 or lower.

In a diagnostic device for a lithium-ion battery according to some embodiments of the present disclosure, the control unit may determine whether the first OCV is 3.0 V or higher.

In a diagnostic device for a lithium-ion battery according to some embodiments of the present disclosure, the control unit may determine whether the inflection point is after 200 cycles.

According to another embodiment of the present disclosure, a diagnostic method for a lithium ion battery may comprise: acquiring a first open circuit voltage (OCV) at a first time point and a second OCV at a second time point; calculating ΔV which is a difference between the first OCV and the second OCV; and comparing at least any one of the first OCV, the inflection point, and AV with a threshold value.

In a diagnostic method for a lithium-ion battery according to some embodiments of the present disclosure, the first OCV may be a first OCV during OCV measurement, and the second OCV may be an OCV at the inflection point.

In a diagnostic method for a lithium ion battery according to some embodiments of the present disclosure, the first OCV and the second OCV may be termination voltages of a rest period after discharging, under a condition that the discharging is performed in a CC mode with a constant current of 1 C up to 2.5 V and then charging is performed in a CC/CV mode with a constant current of 1 C up to 4.2 V (0.1 C cutoff).

In a diagnostic method for a lithium-ion battery according to some embodiments of the present disclosure, in the comparing, it may be determined whether ΔV is 0.120 or lower.

In a diagnostic method for a lithium-ion battery according to some embodiments of the present disclosure, in the comparing, it may be determined whether the first OCV is 3.0 V or higher.

In a diagnostic method for a lithium-ion battery according to some embodiments of the present disclosure, in the comparing, it may be determined whether the inflection point is after 200 cycles.

According to some embodiments of the present disclosure, a lithium-ion battery comprises: an anode comprising Si, in which a first open circuit voltage (OCV) at a first time point and a second OCV at a second time point may be defined, and when a difference between the first OCV and the second OCV is defined as AV, AV may be 0.12 or lower.

In a lithium-ion battery according to some embodiments of the present disclosure, the first OCV may be a first OCV during OCV measurement, and the second OCV may be an OCV at the inflection point.

In a lithium ion battery according to some embodiments of the present disclosure, the first OCV and the second OCV may be termination voltages of a rest period after discharging, under a condition that the discharging is performed in a CC mode with a constant current of 1 C up to 2.5 V and then charging is performed in a CC/CV mode with a constant current of 1 C up to 4.2 V (0.1 C cutoff).

In a lithium-ion battery according to some embodiments of the present disclosure, the first OCV may be 3.0 V or higher.

In a lithium-ion battery according to some embodiments of the present disclosure, the second OCV may be generated after 200 cycles.

In a lithium-ion battery according to some embodiments of the present disclosure, the number of charge and discharge cycles remaining until an end of life (EOL) may be 300 cycles or more.

In a lithium-ion battery according to some embodiments of the present disclosure, the lithium-ion battery may comprise a Si anode, and Si anode may comprise 5 to 15 wt % of Si with respect to a total composition of the Si anode.

According to still another embodiment of the present disclosure, a lithium ion battery may comprise: an anode containing Si, in which, under a condition that discharging is performed in a CC mode with a constant current of 1 C up to 2.5 V and then charging is performed in a CC/CV mode with a constant current of 1 C up to 4.2 V (0.1 C cutoff), a graph obtained when measuring a termination voltage of a rest period after the discharging may comprise an inflection point.

As discussed, the method and system suitably include use of a controller or processer.

In another embodiment, vehicles are provided that comprise an apparatus as disclosed herein.

### BRIEF DESCRIPTION OF THE DRAWINGS

The above and other embodiments, features, and advantages of the present disclosure will become apparent from the detailed description of the following embodiments in conjunction with the accompanying drawings, in which:

FIG. 1 is a block diagram of a diagnostic device according to various embodiments of the present disclosure;

FIG. 2 is a diagram illustrating an example of data acquired by a data acquisition unit;

FIG. 3 is a flowchart of a diagnostic method according to various embodiments of the present disclosure;

FIG. 4 is a diagram illustrating a rest open circuit voltage (OCV) measurement result of a lithium-ion battery containing only graphite;

FIG. 5 is a graph showing the relationship between ΔV and an end of life (EOL);

FIG. 6 is a graph showing the relationship between V1 and EOL; and

FIG. 7 is a graph showing the relationship between an inflection point and EOL.

### DETAILED DESCRIPTION

Hereinafter, embodiments disclosed in the present specification will hereinafter be described in detail with reference to the accompanying drawings. In the following description, identical or similar components are given the same or similar reference numerals and overlapping descriptions thereof may be omitted.

Hereinafter, embodiments disclosed in the present specification will hereinafter be described in detail with reference to the accompanying drawings. In the following description, identical or similar components are given the same or similar reference numerals and overlapping descriptions thereof may be omitted.

In this specification, terms such as “include” or “have” indicate the presence of features, numbers, steps, operations, components, parts, or combinations thereof described in the specification, but do not preclude any of the following: features, numbers, steps, operations, components, parts, or combinations thereof.

In the present specification, when any (e.g., first) component is referred to as “join,” “coupling,” or “connection” or “coupled” or “connected” to another (e.g., second) component with or without the term “functionally” or “communicatively”, it means that any component may be connected to another component directly (e.g., in a wired manner), wirelessly, or through a third component.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

According to some embodiments, the methods according to the various embodiments disclosed in this specification may be included and provided in a computer program product. The computer program product may be traded as a product between a seller and a purchaser. The computer program product may be distributed in the form of a machine-readable storage medium (e.g., compact disc read only memory (CD-ROM)), or may be distributed (e.g., download or upload) through an application store or may be directly distributed (for example, download or upload) between two user devices online. In a case of the online distribution, at least portions of the computer program product may be at least temporarily stored in the storage medium readable by the machine, such as a memory of a server of a manufacturer, a server of an application store, or a relay server or be temporarily created.

According to various embodiments, each component (e.g., a module or a program) of the components described above may comprise a single entity or a plurality of entities, and some of the plurality of entities may be separately disposed in another component. According to various embodiments, one or more of the corresponding components described above and their operations may be omitted or one or more other components or their operations may be added. Alternatively or additionally, a plurality of components (e.g., modules or programs) may be integrated into one component. In this case, the integrated component may perform one or more functions of each component of the plurality of components in such a way that these functions are performed by the corresponding component of the plurality of components before the integration. According to various embodiments, operations performed by the modules, the programs, or the other components may be executed in a sequential manner, a parallel manner, an iterative manner, or a heuristic manner, at least some of the operations may be performed in a different order or be omitted, or one more other operations may be added.

### Diagnostic Device for Lithium Ion Battery

Hereinafter, a diagnostic device for a lithium-ion battery according to various embodiments of the present disclosure will be described.

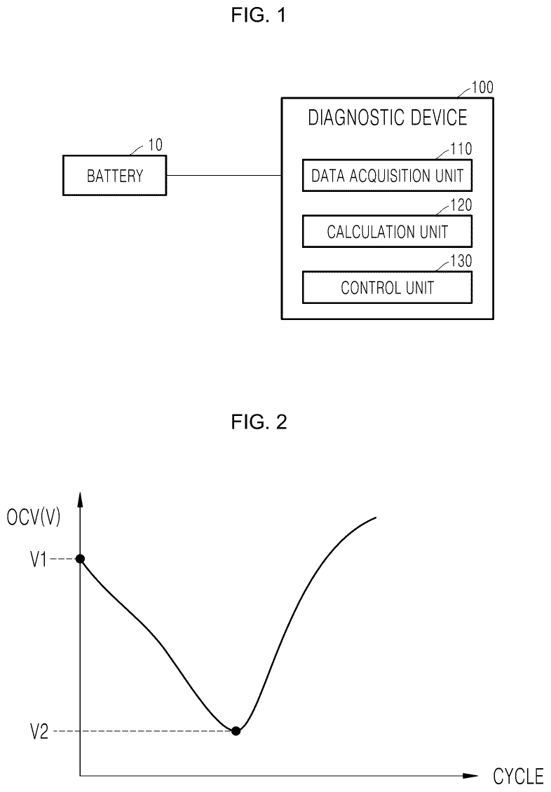

FIG. 1 is a block diagram of a diagnostic device 100 according to various embodiments of the present disclosure. FIG. 2 is a diagram illustrating an example of data acquired by a data acquisition unit.

Referring to FIG. 1, the diagnostic device 100 for a lithium-ion battery according to various embodiments of the present disclosure may comprise a data acquisition unit 110, a calculation unit 120, and a control unit 130.

The data acquisition unit 110 may acquire data related to an open circuit voltage (OCV) of a battery 10 to be diagnosed. The data acquisition unit 110 may acquire data related to a termination voltage (defined as ‘rest OCV’, and hereinafter, the ‘OCV’ and ‘rest OCV’ are used as the same meaning.) of a rest period after discharge under the condition that the battery 10 to be diagnosed is discharged in a CC mode with a constant current of 1 C up to 2.5 V, and then charged in a CC/CV mode with a constant current of 1 C up to 4.2 V (0.1 C cutoff). Here, the rest period may be 10 to 20 minutes. The measurement temperature may be room temperature, for example, 25° C.

Referring to FIG. 2, the data acquisition unit 110 may acquire data related to a first OCV (V1) at a first time point and a second OCV (V2) at a second time point. During the rest OCV measurement, the data acquisition unit 110 may acquire a first OCV (V1) value which is a first rest OCV value, and the second OCV (V2) value which is a rest OCV at an inflection point.

The data acquisition unit 110 may acquire data related to the second time point at which the second OCV (V2) occurs. The data acquisition unit 110 may acquire data related to the inflection point, which is the time point at which the second OCV (V2) occurs.

Although not illustrated in the drawing, the data acquired by the data acquisition unit 110 may be stored in the memory.

The calculation unit 120 may receive data from the data acquisition unit 110 and/or the memory. The calculation unit 120 may perform a calculation based on the received data. For example, the calculation unit 120 may calculate ΔV, which is a difference between the first OCV (V1) and the second OCV (V2).

The control unit 130 may receive data and calculation data from the data acquisition unit 110 and/or the calculation unit 120. The control unit 130 may receive data related to at least any one of the first OCV, the inflection point, and ΔV. The control unit 130 may diagnose the lithium-ion battery based on the received data.

The control unit 130 may compare at least any one of the first OCV, the inflection point, and ΔV with a threshold value. Alternatively, the control unit 130 may compare at least any two of the first OCV, the inflection point, and ΔV with the threshold value. Alternatively, the control unit 130 may compare all of the first OCV, the inflection point, and ΔV with the threshold value.

The control unit 130 may diagnose the lithium-ion battery based on data related to the first OCV (V1) received from the data acquisition unit 110. For example, the control unit 130 may determine whether the first OCV (V1) is 3.0 V or higher. When the control unit 130 determines that the first OCV (V1) is 3.0 V or higher, the control unit 130 may determine that the performance of the battery 10 to be diagnosed is higher than or equal to a standard. When the control unit 130 determines that the first OCV (V1) is 3.0 V or higher, the control unit 130 may determine that the performance of the battery 10 to be diagnosed is excellent. When the control unit 130 determines that the first OCV (V1) is below 3.0 V, the control unit 130 may determine that the performance of the battery 10 to be diagnosed is below the standard. When the control unit 130 determines that the first OCV (V1) is below 3.0 V, the control unit 130 may determine that the performance of the battery 10 to be diagnosed is below the standard.

The control unit 130 may diagnose the lithium-ion battery based on data related to the inflection point received from the data acquisition unit 110. For example, the control unit 130 may determine whether the inflection point is after 200 cycles. When the control unit 130 determines that the inflection point is 200 cycles or more, the control unit 130 may determine that the performance of the battery 10 to be diagnosed is higher than or equal to the standard. When the control unit 130 determines that the inflection point is 200 cycles or more, the control unit 130 may determine that the performance of the battery 10 to be diagnosed is excellent. When the control unit 130 determines that the inflection point is below 200 cycles, the control unit 130 may determine that the performance of the battery 10 to be diagnosed is below the standard. When the control unit 130 determines that the inflection point is below 200 cycles, the control unit 130 may determine that the performance of the battery 10 to be diagnosed is below the standard.

Alternatively, the control unit 130 may determine whether the inflection point is after 150 cycles. When the control unit 130 determines that the inflection point is 150 cycles or more, the control unit 130 may determine that the performance of the battery 10 to be diagnosed is higher than or equal to the standard. When the control unit 130 determines that the inflection point is 150 cycles or more, the control unit 130 may determine that the performance of the battery 10 to be diagnosed is excellent. When the control unit 130 determines that the inflection point is below 150 cycles, the control unit 130 may determine that the performance of the battery 10 to be diagnosed is below the standard. When the control unit 130 determines that the inflection point is below 150 cycles, the control unit 130 may determine that the performance of the battery 10 to be diagnosed is below the standard.

The control unit 130 may diagnose the lithium-ion battery based on data related to ΔV received from the calculation unit 120. For example, the control unit 130 may determine whether ΔV is 0.120 or less. When the control unit 130 determines that ΔV is 0.120 or less, the control unit 130 may determine that the performance of the battery 10 to be diagnosed is higher than or equal to the standard. When the control unit 130 determines that ΔV is 0.120 or less, the control unit 130 may determine that the performance of the battery 10 to be diagnosed is excellent. When the control unit 130 determines that ΔV exceeds 0.120, the control unit 130 may determine that the performance of the battery 10 to be diagnosed is below the standard. When the control unit 130 determines that ΔV exceeds 0.120, the control unit 130 may determine that the performance of the battery 10 to be diagnosed is below the standard.

In a lithium-ion battery in which at least any one of the first OCV, the inflection point, and ΔV satisfies the threshold value, the number of charge and discharge cycles remaining until an end of life (EOL) may be 300 cycles or more. In the lithium-ion battery in which at least any one of the first OCV, the inflection point, and ΔV satisfies the threshold value, a state of health (SOH) 70% may be 300 cycles or more. Therefore, the lithium-ion battery in which at least any one of the first OCV, the inflection point, and ΔV satisfies the threshold value may be diagnosed as having excellent performance.

According to the diagnostic device for a lithium-ion battery according to various embodiments of the present disclosure, it is possible to present a new standard for predicting accurate performance for a lithium-ion battery. According to the diagnostic device for a lithium-ion battery according to various embodiments of the present disclosure, it is possible to present a new standard for predicting accurate performance for, particularly, a lithium-ion battery including an Si anode. As a result, when designing the anode containing Si as the anode active material, it is possible to provide a guideline for securing excellent performance.

### Diagnostic Method for Lithium Ion Battery

Hereinafter, a diagnostic method for a lithium-ion battery according to various embodiments of the present disclosure will be described.

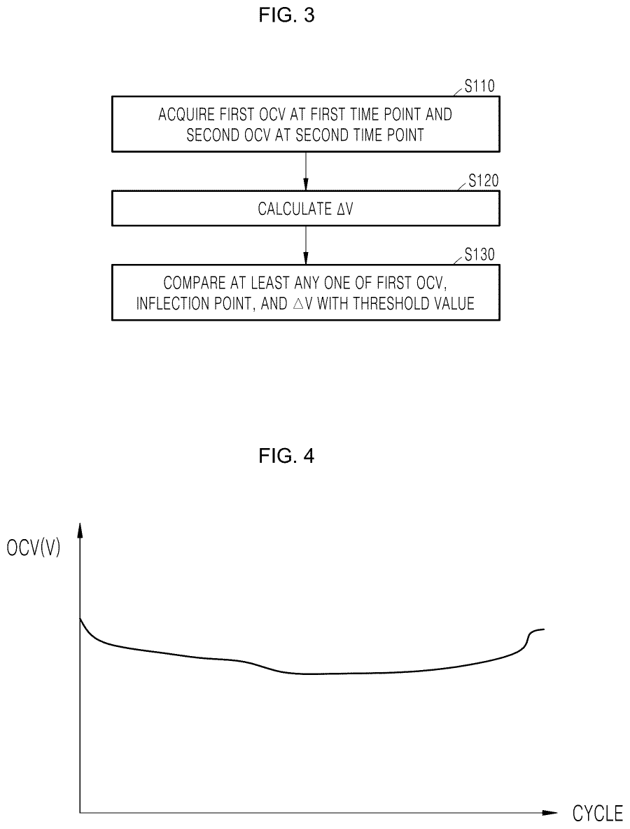

FIG. 3 is a flowchart of a diagnostic method according to various embodiments of the present disclosure.

Referring to FIG. 3, the diagnostic method according to various embodiments of the present disclosure may comprise a step (S110) of acquiring a first OCV at a first time point and a second OCV at a second time point; a step (S120) of calculating ΔV; and a step (S130) of comparing at least any one of the first OCV, the inflection point, and ΔV with a threshold value. The diagnostic method according to various embodiments of the present disclosure may be performed by the diagnostic device described above.

In the acquiring step (S110), the data related to the termination voltage of the rest period after the discharge may be acquired under the condition that the battery to be diagnosed is discharged in the CC mode with a constant current of 1 C up to 2.5 V, and then charged in the CC/CV mode with a constant current of 1 C up to 4.2 V (0.1 C cutoff). Here, the rest period may be 10 to 20 minutes. The measurement temperature may be room temperature, for example, 25° C.

In the acquiring step (S110), the data related to the first OCV (V1) at the first time point and the second OCV (V2) at the second time point may be acquired. In the acquiring step (S110), during the rest OCV measurement, the first OCV (V1) value which is the first rest OCV value and the second OCV (V2) value which is the rest OCV at the inflection point may be acquired.

Meanwhile, in the acquiring step (S110), the data related to the second time point at which the second OCV (V2) occurs may be acquired. In the acquiring step (S110), the data related to the inflection point, which is the time point at which the second OCV (V2) occurs, may be acquired.

Next, in the calculating step (S120), ΔV, which is the difference between the first OCV (V1) and the second OCV (V2), may be calculated.

In the comparing step (S130), at least any one of the first OCV, the inflection point, and ΔV may be compared with a threshold value. Alternatively, in the comparing step (S130), at least any two of the first OCV, the inflection point, and ΔV may be compared with the threshold value. Alternatively, in the comparing step (S130), all of the first OCV, the inflection point, and ΔV may be compared with the threshold value.

For example, in the comparing step (S130), it may be determined whether the first OCV (V1) is 3.0 V or higher. When it is determined in the comparing step (S130) that the first OCV (V1) is 3.0 V or higher, it may be diagnosed that the performance of the battery to be diagnosed is higher than or equal to the standard. When it is determined in the comparing step (S130) that the first OCV (V1) is 3.0 V or higher, it may be diagnosed that the performance of the battery to be diagnosed is excellent. When it is determined in the comparing step (S130) that the first OCV (V1) is below 3.0 V, it may be diagnosed that the performance of the battery to be diagnosed is below the standard. When it is determined in the comparing step (S130) that the first OCV (V1) is below 3.0 V, it may be diagnosed that the performance of the battery to be diagnosed is below the standard.

In the comparing step (S130), it may be determined whether the inflection point is after 200 cycles. When it is determined in the comparing step (S130) that the inflection point is 200 cycles or more, it may be diagnosed that the performance of the battery to be diagnosed is higher than or equal to the standard. When it is determined in the comparing step (S130) that the inflection point is 200 cycles or more, it may be diagnosed that the performance of the battery to be diagnosed is excellent. When it is determined in the comparing step (S130) that the inflection point is below 200 cycles, it may be diagnosed that the performance of the battery to be diagnosed is below the standard. When it is determined in the comparing step (S130) that the inflection point is below 200 cycles, it may be diagnosed that the performance of the battery to be diagnosed is below the standard.

Alternatively, in the comparing step (S130), it may be determined whether the inflection point is after 150 cycles. When it is determined in the comparing step (S130) that the inflection point is 150 cycles or more, it may be diagnosed that the performance of the battery 10 to be diagnosed is higher than or equal to the standard. When it is determined in the comparing step (S130) that the inflection point is 150 cycles or more, it may be diagnosed that the performance of the battery 10 to be diagnosed is excellent. When it is determined in the comparing step (S130) that the inflection point is below 150 cycles, it may be diagnosed that the performance of the battery to be diagnosed is below the standard. When it is determined in the comparing step (S130) that the inflection point is below 150 cycles, it may be diagnosed that the performance of the battery 10 to be diagnosed is below the standard.

In the comparing step (S130), it may be determined whether ΔV is 0.120 or less. When it is determined in the comparing step (S130) that ΔV is 0.120 or less, it may be diagnosed that the performance of the battery to be diagnosed is higher than or equal to the standard. When it is determined in the comparing step (S130) that ΔV is 0.120 or less, it may be diagnosed that the performance of the battery to be diagnosed is excellent. When it is determined in the comparing step (S130) that ΔV exceeds 0.120, it may be diagnosed that the performance of the battery 10 to be diagnosed is below the standard. When it is determined in the comparing step (S130) that ΔV exceeds 0.120, it may be diagnosed that the performance of the battery to be diagnosed is below the standard.

In the lithium-ion battery in which at least any one of the first OCV, the inflection point, and ΔV satisfies the threshold value, the number of charge and discharge cycles remaining until the end of life (EOL) may be 300 cycles or more. In the lithium-ion battery in which at least any one of the first OCV, the inflection point, and ΔV satisfies the threshold value, a state of health (SOH) 70% may be 300 cycles or more. Therefore, it may be diagnosed that the lithium-ion battery in which at least any one of the first OCV, the inflection point, and ΔV satisfies the threshold value has excellent performance.

According to the diagnostic method for a lithium-ion battery according to various embodiments of the present disclosure, it is possible to present a new standard for predicting accurate performance for a lithium-ion battery. According to the diagnostic method for a lithium-ion battery according to various embodiments of the present disclosure, it is possible to present a new standard for predicting accurate performance for a lithium-ion battery including an Si anode. As a result, when designing the anode containing Si as the anode active material, it is possible to provide a guideline for securing excellent performance.

### Lithium Ion Battery

Hereinafter, a lithium-ion battery according to various embodiments of the present disclosure will be described. A lithium-ion battery according to various embodiments of the present disclosure may have a specific open circuit voltage (OCV).

Specifically, under the condition that the lithium ion battery according to various embodiments of the present disclosure is discharged in the CC mode with a constant current of 1 C up to 2.5 V and then charged in the CC/CV mode with a constant current of 1 C up to 4.2 V (0.1 C cutoff), the termination voltage of the rest period after discharging may have a specific voltage value. Here, the rest period may be 10 to 20 minutes. The measurement temperature of the rest OCV may be room temperature.

Referring to FIG. 2, the lithium-ion battery according to various embodiments of the present disclosure may comprise at least any one inflection point in the graph obtained during the rest OCV measurement.

According to various embodiments of the present disclosure, the lithium-ion battery is defined as having the first OCV (V1) at the first time point, the second OCV (V2) at the second time point, and when the difference between the first OCV (V1) and the second OCV (V2) is defined as ΔV, ΔV is 0.12 or less. Preferably, ΔV may be from 0.03 to 0.12. Alternatively, ΔV may be from 0.04 to 0.12. Alternatively, ΔV may be from 0.05 to 0.12. Alternatively, ΔV may be from 0.06 to 0.12. Alternatively, ΔV may be from 0.065 to 0.12. Alternatively, ΔV may be from 0.065 to 0.11.

The first OCV (V1) may be the first OCV in the rest OCV measurement, and the second OCV (V2) may be the rest OCV at the inflection point.

The first OCV (V1) of the lithium-ion battery according to various embodiments of the present disclosure may be 3.0 V or higher.

The lithium-ion battery according to various embodiments of the present disclosure may cause the second OCV (V2) to occur after 200 cycles. That is, the inflection point may occur after 200 cycles during the rest OCV measurement. Alternatively, the second OCV (V2) may occur after 150 cycles.

The lithium-ion battery according to various embodiments of the present disclosure may satisfy at least any one of the following conditions (1) to (3). The lithium-ion battery according to various embodiments of the present disclosure may satisfy at least two of the following conditions (1) to (3). The lithium-ion battery according to various embodiments of the present disclosure may satisfy all of the following conditions (1) to (3).

$$V 1 \geq 3. V \qquad Condition ( 1 )$$

$$Δ V ( V 1 - V 2 ) \leq 0.12 V \qquad Condition ( 2 )$$

$$inflection point \geq 200 cycles \qquad Condition ( 3 )$$

In the lithium-ion battery according to various embodiments of the present disclosure, the number of charge and discharge cycles remaining until the EOL may be 300 cycles or more. Alternatively, the number of charge and discharge cycles remaining until the EOL may be 350 cycles or more. Alternatively, the number of charge and discharge cycles remaining until the EOL may be 300 to 800 cycles.

Alternatively, in the lithium-ion battery according to various embodiments of the present disclosure, the SOH 70% may be 300 cycles or more. Alternatively, the SOH 70% may be 350 cycles or more. Alternatively, the SOH 70% may be 300 to 800 cycles.

The anode of the lithium-ion battery according to various embodiments of the present disclosure may have a capacity of 380 to 500 mAh/g.

The anode of the lithium-ion battery according to various embodiments of the present disclosure may comprise silicon (Si) as an anode active material. Si may comprise 5 to 15 wt % with respect to a total composition of the anode. The anode of the lithium-ion battery according to various embodiments of the present disclosure may further comprise graphite as an anode active material. The anode of the lithium-ion battery according to various embodiments of the present disclosure does not comprise only graphite as the anode active material.

The anode of the lithium-ion battery according to various embodiments of the present disclosure may further comprise a conductive material, a binder, and a thickener.

The conductive material may comprise at least any one selected from the group consisting of natural graphite, artificial graphite, carbon black, acetylene black, Ketjen black, channel black, paneth black, lamp black, thermal black, conductive fiber, fluorocarbon, aluminum powder, nickel powder, zinc oxide, potassium titanate, titanium oxide, polyphenylene derivatives, carbon nanotube, plate-like graphite, graphene, graphene oxide, and graphite flake.

The binder and/or thickener may comprise at least any one selected from the group consisting of polyvinylidene fluoride-hexafluoropropylene copolymer (PVDF-co-HFP), polyvinylidene fluoride, polyacrylonitrile, polymethylmethacrylate, polyvinyl alcohol, carboxymethyl cellulose (CMC), starch, hydroxypropyl cellulose, regenerated cellulose, polyvinyl pyrrolidone, tetrafluoroethylene, polyethylene, polypropylene, polyacrylic acid, ethylene-propylene-diene monomer (EPDM), sulfonated EPDM, styrene butadiene rubber (SBR), fluoroelastomer, and poly acrylic acid, and may also comprise various copolymers thereof.

The lithium-ion battery according to various embodiments of the present disclosure may comprise a cathode. The cathode may comprise a cathode active material, a conductive material, and a binder. The cathode active material may comprise at least any one selected from the group consisting of, for example, nickel cobalt manganese (NCM), nickel cobalt aluminum (NCA), lithium manganese oxide (LMO), lithium cobalt oxide (LCO), and lithium iron phosphate (LFP). Preferably, the cathode active material may comprise NCM.

The conductive material may comprise at least any one selected from the group consisting of natural graphite, artificial graphite, carbon black, acetylene black, Ketjen black, channel black, paneth black, lamp black, thermal black, conductive fiber, fluorocarbon, aluminum powder, nickel powder, zinc oxide, potassium titanate, titanium oxide, polyphenylene derivatives, carbon nanotube, plate-like graphite, graphene, graphene oxide, and graphite flake.

The binder may comprise at least any one selected from the group consisting of polyvinylidene fluoride-hexafluoropropylene copolymer (PVDF-co-HFP), polyvinylidene fluoride, polyacrylonitrile, polymethylmethacrylate, polyvinyl alcohol, carboxymethyl cellulose (CMC), starch, hydroxypropyl cellulose, regenerated cellulose, polyvinyl pyrrolidone, tetrafluoroethylene, polyethylene, polypropylene, polyacrylic acid, ethylene-propylene-diene monomer (EPDM), sulfonated EPDM, styrene butadiene rubber (SBR), fluoroelastomer, and poly acrylic acid, and may also comprise various copolymers thereof.

The lithium-ion battery according to various embodiments of the present disclosure may comprise a separator and an electrolyte between the cathode and the anode.

The separator may separate the anode and the cathode and provide a passage through which lithium ions move. The separator may comprise a porous polymer film, for example, a porous polymer film made of a polyolefin-based polymer such as an ethylene homopolymer, a propylene homopolymer, an ethylene/butene copolymer, an ethylene/hexene copolymer, and an ethylene/methacrylate copolymer, or a laminated structure of two or more layers thereof. Alternatively, the separator may comprise a nonwoven fabric made of high-melting-point glass fibers, polyethylene terephthalate fibers, and the like.

The electrolyte may comprise an organic liquid electrolyte, an inorganic liquid electrolyte, a solid polymer electrolyte, a gel-type polymer electrolyte, a solid inorganic electrolyte, a molten inorganic electrolyte, and the like.

According to the lithium-ion battery according to various embodiments of the present disclosure, it is possible to secure excellent performance by satisfying new characteristic values in a lithium-ion battery including an Si anode.

### Example

Various lithium-ion batteries including NCM as a cathode active material and Si as an anode active material were prepared. The Si content of the prepared lithium-ion batteries was 5 to 15 wt %, and the capacity was 380 to 500 mAh/g. The rest OCV was measured for the batteries.

Under the condition that the rest OCV is discharged in the CC mode with a constant current of 1 C up to 2.5 V and then charged in the CC/CV mode with a constant current of 1 C up to 4.2 V (0.1 C cutoff), the termination voltage of the rest period after the discharging was measured.

During the rest OCV measurement, data related to V1, the first OCV, V2, the rest OCV at the inflection point, the inflection point, and ΔV were obtained based on the measurement results.

The results are as in Table 1 below.

TABLE 1

| | V1 | Inflection point | V2 | ΔV | EOL | Si content |
|---|---|---|---|---|---|---|
| No. | (V) | (cycle) | (V) | (V) | (cycle) | (wt %) |
| 1 | 3.03 | 400 | 3.03 | 0.07 | 700 | 5 |
| 2 | 3.03 | 300 | 3.03 | 0.07 | 680 | 5 |
| 3 | 3.04 | 400 | 3.03 | 0.08 | 620 | 6 |
| 4 | 3.03 | 400 | 3.01 | 0.09 | 600 | 7 |
| 5 | 3.01 | 320 | 2.99 | 0.09 | 600 | 8 |
| 6 | 3.03 | 300 | 3.035 | 0.065 | 580 | 9 |
| 7 | 3.03 | 300 | 3.02 | 0.08 | 550 | 9 |
| 8 | 3.02 | 300 | 3.02 | 0.07 | 550 | 10 |
| 9 | 3.02 | 300 | 3.02 | 0.07 | 520 | 10 |
| 10 | 3.01 | 280 | 3.015 | 0.065 | 500 | 11 |
| 11 | 3 | 220 | 2.98 | 0.09 | 490 | 12 |
| 12 | 3 | 240 | 2.97 | 0.1 | 460 | 14 |
| 13 | 3.01 | 200 | 2.97 | 0.11 | 430 | 14 |
| 14 | 3.03 | 220 | 2.98 | 0.12 | 370 | 15 |
| 15 | 2.99 | 120 | 2.93 | 0.13 | 240 | 5 |
| 16 | 2.98 | 120 | 2.92 | 0.13 | 220 | 5 |
| 17 | 2.97 | 150 | 2.93 | 0.14 | 220 | 6 |
| 18 | 2.96 | 150 | 2.94 | 0.15 | 220 | 7 |
| 19 | 2.99 | 120 | 2.92 | 0.14 | 210 | 8 |
| 20 | 2.96 | 140 | 2.9 | 0.17 | 210 | 9 |
| 21 | 2.99 | 140 | 2.85 | 0.21 | 200 | 9 |
| 22 | 2.99 | 140 | 2.88 | 0.18 | 200 | 10 |
| 23 | 2.96 | 130 | 2.92 | 0.17 | 200 | 10 |
| 24 | 2.99 | 130 | 2.85 | 0.21 | 190 | 11 |
| 25 | 2.97 | 130 | 2.87 | 0.17 | 190 | 12 |
| 26 | 2.98 | 125 | 2.87 | 0.18 | 180 | 14 |
| 27 | 2.97 | 120 | 2.85 | 0.19 | 180 | 14 |
| 28 | 2.98 | 120 | 2.86 | 0.19 | 160 | 15 |
| 29 | 2.97 | 110 | 2.85 | 0.19 | 160 | 15 |

Meanwhile, for comparison, the rest OCV was measured using the above method for a lithium-ion battery that does not contain Si as an anode active material and contains only graphite. FIG. 4 is a diagram illustrating a rest OCV measurement result of a lithium-ion battery containing only graphite. Referring to FIG. 4, it can be seen that no distinct inflection point occurs, and the voltage gradually decreases as the cycle progresses, and then increases at the end of the cycle. In other words, it can be seen that it has a different trend from a battery that contains Si as an anode active material.

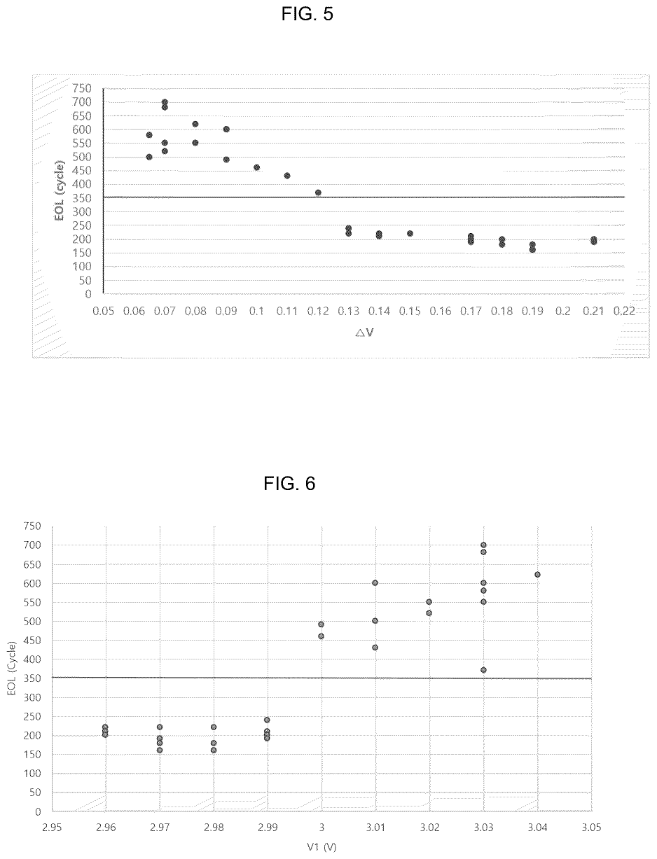

FIG. 5 is a graph showing the relationship between ΔV and EOL in the measurement results of Table 1 above.

Meanwhile, when the number of charge and discharge cycles remaining until EOL is 350 cycles or more, it can be determined that the battery is excellent in remaining life and performance. Referring to FIG. 5, it can be confirmed that EOL is 350 or more when ΔV is 0.120 or less regardless of the Si content. That is, when ΔV exceeds 0.120, it can be confirmed that EOL decreases.

FIG. 6 is a graph showing the relationship between V1 and EOL in the measurement results of Table 1 above.

Referring to FIG. 6, it can be confirmed that EOL is 350 or more when V1 is 3.0 V or higher regardless of the Si content. That is, it can be confirmed that EOL decreases when V1 is less than 3.0 V.

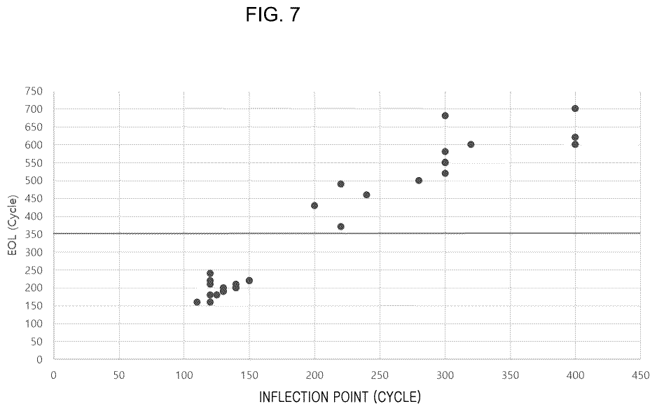

FIG. 7 is a graph showing the relationship between the inflection point and EOL in the measurement results of Table 1 above.

Referring to FIG. 7, it can be confirmed that EOL is 350 or more when the inflection point occurs after 200 cycles regardless of the Si content. That is, it can be seen that EOL decreases when the inflection point occurs before 200 cycles.

Through the above results, it can be seen that excellent performance can be secured by satisfying new characteristic values in a lithium-ion battery including an Si anode. In addition, when designing the anode containing Si as the anode active material, it is possible to provide a guideline for securing excellent performance.

According to the diagnostic device and method for a lithium-ion battery according to various embodiments of the present disclosure, it is possible to present a new standard for predicting accurate performance for a lithium-ion battery including a Si anode. According to the diagnostic device and method for a lithium-ion battery according to various embodiments of the present disclosure, it is possible to provide a guideline for securing excellent performance when designing an anode containing Si as an anode active material.

According to the lithium-ion battery according to various embodiments of the present disclosure, it is possible to secure excellent performance by satisfying new characteristic values in a lithium-ion battery including an Si anode.

The effects of the present disclosure are not limited to those mentioned above, and other effects not mentioned can be clearly understood by those skilled in the art from the following description.

Hereinabove, embodiments of the present disclosure have been described with drawings. This is illustrative, and the present disclosure is not limited to the contents of the above-described embodiments and drawings.

It is obvious to those skilled in the art that the present disclosure may be modified within the scope of the disclosed technical idea. The described embodiments should be viewed as part of the present disclosure, and the scope of the present disclosure should not be limited only through the described embodiments.

The scope of the present disclosure should be judged by the technical idea described in the claims. In addition, even if the actions or effects according to the configuration are not explicitly described while describing the embodiments of the present disclosure, it is obvious that the actions or effects that are predictable by the configuration should be recognized as the present disclosure.

1. A diagnostic device for a lithium-ion battery, the diagnostic device comprising:
a data acquisition unit configured to acquire a first open circuit voltage (OCV) at a first time point and a second OCV at a second time point;
a calculation unit configured to calculate ΔV which is a difference between the first OCV and the second OCV; and
a control unit configured to compare at least any one of the first OCV, an inflection point, and the ΔV with a threshold value.

2. The diagnostic device of claim 1, wherein the first OCV is an OCV measured first during OCV measurement, and
the second OCV is an OCV at the inflection point.

3. The diagnostic device of claim 1, wherein the first OCV and the second OCV are termination voltages of a rest period after discharging, under a condition that the discharging is performed in a CC mode with a constant current of about 1 C up to 2.5 V and then charging is performed in a CC/CV mode with a constant current of about 1 C up to 4.2 V (0.1 C cutoff).

4. The diagnostic device of claim 1, wherein the control unit is configured to determine whether the ΔV is about 0.120 or lower.

5. The diagnostic device of claim 1, wherein the control unit is configured to determine whether the first OCV is about 3.0 V or higher.

6. The diagnostic device of claim 1, wherein the control unit is configured to determine whether the second OCV is generated after about 200 charge and discharge cycles.

7. A diagnostic method for a lithium-ion battery, the method comprising:
acquiring a first open circuit voltage (OCV) at a first time point and a second OCV at a second time point;
calculating ΔV which is a difference between the first OCV and the second OCV; and
comparing at least any one of the first OCV, an inflection point, and the ΔV with a threshold value.

8. The diagnostic method of claim 7, wherein the first OCV is an OCV measured first during OCV measurement, and
the second OCV is an OCV at the inflection point.

9. The diagnostic method of claim 7, wherein the first OCV and the second OCV are termination voltages of a rest period after discharging, under a condition that the discharging is performed in a CC mode with a constant current of about 1 C up to 2.5 V and then charging is performed in a CC/CV mode with a constant current of about 1 C up to 4.2 V (0.1 C cutoff).

10. The diagnostic method of claim 7, wherein in the comparing, it is determined whether the ΔV is about 0.120 or lower.

11. The diagnostic method of claim 7, wherein in the comparing, it is determined whether the first OCV is about 3.0 V or higher.

12. The diagnostic method of claim 7, wherein in the comparing, it is determined whether the second OCV is generated after about 200 charge and discharge cycles.

13. A lithium-ion battery comprising:
an anode comprising Si,
wherein a first open circuit voltage (OCV) at a first time point and a second OCV at a second time point are defined, and
when a difference between the first OCV and the second OCV is defined as ΔV, the ΔV is about 0.12 or lower.

14. The lithium-ion battery of claim 13, wherein the first OCV is an OCV measured first during OCV measurement, and
the second OCV is an OCV at an inflection point.

15. The lithium ion battery of claim 13, wherein the first OCV and the second OCV are termination voltages of a rest period after discharging, under a condition that the discharging is performed in a CC mode with a constant current of about 1 C up to 2.5 V and then charging is performed in a CC/CV mode with a constant current of about 1 C up to 4.2 V (0.1 C cutoff).

16. The lithium-ion battery of claim 13, wherein the first OCV is about 3.0 V or higher.

17. The lithium-ion battery of claim 13, wherein the second OCV is generated after 200 charge and discharge cycles.

18. The lithium-ion battery of claim 13, wherein the number of charge and discharge cycles remaining until an end of life (EOL) is about 300 cycles or more.

19. The lithium-ion battery of claim 13, wherein the lithium-ion battery comprises the Si anode, and
the Si anode comprises about 5 to 15 wt % of Si with respect to a total composition of the Si anode.

20. The lithium-ion battery of claim 13, wherein an anode of the lithium-ion battery has a capacity of about 380 to 500 mAh/g.
